(19) United States
(12) Patent Application Publication
(10) Pub. No.: US 2025/0353137 A1
(43) Pub. Date: Nov. 20, 2025

(54) POLISHING PAD FOR CHEMICAL MECHANICAL POLISHING

(71) Applicant: SAMSUNG ELECTRONICS CO., LTD., Suwon-si (KR)

(72) Inventors: Myeong Jin LEE, Suwon-si (KR); Suk Hoon JEONG, Suwon-si (KR)

(73) Assignee: SAMSUNG ELECTRONICS CO., LTD., Suwon-si (KR)

(21) Appl. No.: 18/974,229

(22) Filed: Dec. 9, 2024

(30) Foreign Application Priority Data
May 14, 2024 (KR) 10-2024-0063434

(51) Int. Cl. B24B 37/24; B24B 37/22; B24B 37/26

(52) U.S. Cl. CPC B24B 37/245; B24B 37/22; B24B 37/26

(57) ABSTRACT

A chemical mechanical polishing (CMP) polishing pad includes a base layer, a polishing layer on the base layer and having a concave-convex pattern shape, and a coating layer on the polishing layer and comprising diamond particles.

### CROSS-REFERENCE TO RELATED APPLICATION

This application is based on and claims priority to Korean Patent Application No. 10-2024-0063434, filed on May 14, 2024, in the Korean Intellectual Property Office, the disclosure of which is incorporated by reference herein in its entirety.

### BACKGROUND

Example embodiments of the disclosure relate to a polishing pad for chemical mechanical polishing (CMP).

In a manufacturing process of a semiconductor device, a chemical mechanical polishing (CMP) process is widely used as a planarization scheme to remove a step between films formed on a substrate. The CMP process may efficiently planarize the films formed on the substrate by injecting a polishing slurry containing abrasive particles into between the substrate and the polishing pad and rubbing the substrate and the polishing pad against each other.

During the CMP process, the polishing pad may be filled with a SiO₂ film when processing the SiO₂ film, causing clogging or glazing in the CMP process, thereby reducing a polishing rate.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a chemical mechanical polishing (CMP) polishing pad that may be capable of increasing a polishing rate.

Additional aspects will be set forth in part in the description which follows and, in part, will be apparent from the description, or may be learned by practice of the presented embodiments.

According to an aspect of an example embodiment, a CMP polishing pad may include a base layer, a polishing layer on the base layer and having a concave-convex pattern shape, and a coating layer on the polishing layer and comprising diamond particles.

According to an aspect of an example embodiment, a CMP polishing pad may include a base layer including a center area, a polishing layer including a first polishing layer on the center area and a second polishing layer on the base layer and at least partially surrounding the first polishing layer, where the second polishing layer is spaced apart from the first polishing layer, and a coating layer on the polishing layer and including a polymer and diamond particles, where the first polishing layer and the second polishing layer have a concave-convex pattern shape, the first polishing layer includes a first horizontal portion and a first plurality of protrusions, and the second polishing layer includes a second horizontal portion and a second plurality of protrusions.

According to an aspect of an example embodiment, a CMP polishing pad may include a base layer including a first portion extending in a horizontal direction and a second portion extending in a vertical direction and from the first portion, polishing layer on the base layer and having a concave-convex pattern shape, where the polishing layer includes a horizontal portion and a plurality of protrusions, and a coating layer on the polishing layer and including a polymer and diamond particles, where the second portion contacts at least a portion of a side surface of the horizontal portion.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a perspective view illustrating a chemical mechanical polishing (CMP) device equipped with a CMP polishing pad according to one or more embodiments;

FIG. 2 is a diagram illustrating a CMP polishing pad according to one or more embodiments;

FIG. 3 is a cross-sectional view taken along A-A in FIG. 2 according to one or more embodiments;

FIG. 4 and FIG. 5 are enlarged views of examples of portion P of FIG. 3 according to one or more embodiments;

FIG. 6 and FIG. 7 are diagrams illustrating a CMP polishing pad according to one or more embodiments;

FIG. 8 and FIG. 9 are diagrams illustrating a CMP polishing pad according to one or more embodiments;

FIG. 10 to FIG. 11 are diagrams illustrating a CMP polishing pad according to one or more embodiments;

FIG. 12 is a cross-sectional view taken along B-B in FIG. 10 and FIG. 11 according to one or more embodiments;

FIG. 13 to FIG. 16 are diagrams illustrating a CMP polishing pad according to one or more embodiments; and

FIG. 17 to FIG. 22 are diagrams illustrating a method for manufacturing a CMP polishing pad according to one or more embodiments.

### DETAILED DESCRIPTIONS

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

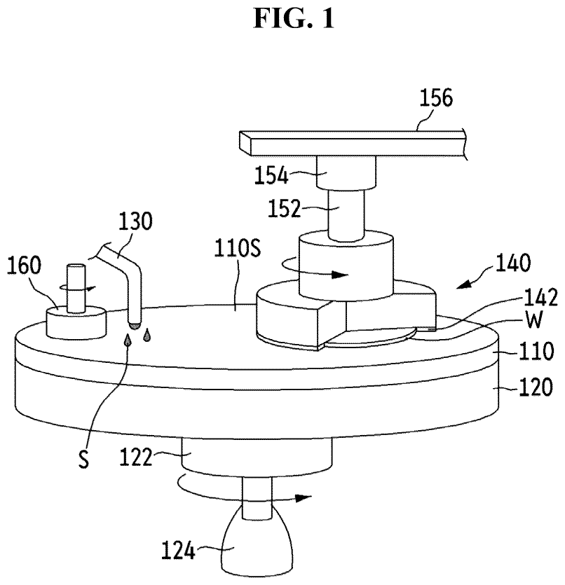

FIG. 1 is a perspective view illustrating a chemical mechanical polishing (CMP) device equipped with a CMP polishing pad according to one or more embodiments.

Referring to FIG. 1, a CMP device equipped with a CMP polishing pad according to one or more embodiments may include a polishing pad 110, a platen 120, a slurry supply 130, a carrier head assembly 140 and a pad conditioner 160.

The polishing pad 110 may be disposed on the platen 120. The polishing pad 110 may be provided in a form of a plate having a certain thickness (for example, a circular plate). However, embodiments are not limited thereto. The polishing pad 110 may include a polishing surface 110S facing a wafer W. The polishing surface 110S may have a predetermined roughness. For example, the polishing surface 110S may have a concave-convex pattern. While the polishing process is performed, the polishing surface 110S may contact the wafer W to polish the wafer W.

The polishing pad 110 may have a plurality of grooves defined therein. The grooves may be formed in the polishing surface 110S of the polishing pad 110. For example, individual grooves may be formed by recessing the polishing surface 110S. While the polishing process is performed, the grooves may be provided as passageways for the polishing slurry S to facilitate the flow of the polishing slurry S.

The platen 120 may support the polishing pad 110 thereon. For example, the polishing pad 110 may be disposed on an upper surface of the platen 120. Furthermore, the platen 120 may be rotatable. The rotatable platen 120 may rotate the polishing pad 110 disposed on the platen 120. For example, a first drive shaft 122 connected to a bottom of the platen 120 may rotate upon receiving a rotational power from a first motor 124. This platen 120 may rotate the polishing pad 110 about a rotation axis perpendicular to the upper surface of the platen 120.

The slurry supply 130 may be disposed adjacent to the polishing pad 110. While the polishing process is performed, the slurry supply 130 may supply the polishing slurry S onto the polishing surface 110S of the polishing pad 110. The polishing slurry S may be smoothly supplied to between the wafer W and the polishing pad 110 through the grooves formed in the polishing surface 110S.

In one or more embodiments, the polishing slurry S may contain therein a plurality of abrasive particles. For example, the polishing slurry S may include a reactive agent and/or a chemical reaction catalyst in which abrasive particles are dispersed. The abrasive particles may function as an abrasive. The abrasive particle may include, for example, metal oxide, metal oxide coated with an organic or inorganic material, or metal oxides in a colloidal state. For example, the abrasive particle may include at least one of silica, alumina, ceria, titania, zirconia, magnesia, germania, mangania, and combinations thereof. However, embodiments are not limited thereto.

The carrier head assembly 140 may be disposed adjacent to the polishing pad 110. The carrier head assembly 140 may provide the wafer W on the polishing surface 110S of the polishing pad 110. For example, the carrier head assembly 140 may operate to hold the wafer W against the polishing pad 110.

In one or more embodiments, the carrier head assembly 140 may independently control polishing parameters (e.g., pressure, etc.) respectively related to the wafers W. For example, the carrier head assembly 140 may include a flexible membrane and a retaining ring 142 for retaining the wafer W under the flexible membrane. This carrier head assembly 140 may include a plurality of independently controllable pressurizable chambers defined by the flexible membrane. The pressurizable chambers may respectively apply independently controllable pressures to relevant regions on the flexible membrane or on the wafer W.

The carrier head assembly 140 may be rotatable. The rotatable carrier head assembly 140 may rotate the wafer W fixed to the carrier head assembly 140. For example, a second drive shaft 152 connected to a top of the carrier head assembly 140 may rotate upon receiving a rotational power from a second motor 154.

The carrier head assembly 140 may be supported by a support structure 156. The support structure 156 may be, for example, a carousel or a track. However, embodiments are not limited thereto. In one or more embodiments, the carrier head assembly 140 may translate laterally across an upper surface of polishing pad 110. For example, the carrier head assembly 140 may vibrate on a slider of the support structure 156, or via rotational vibration of the support structure 156 itself.

In FIG. 1, only one carrier head assembly 140 is shown as being provided on the polishing pad 110, but this is only an example. In one or more embodiments, in order to efficiently use a surface area of the polishing pad 110, a plurality of carrier head assemblies 140 may be provided on the polishing pad 110. In addition, in FIG. 1, a rotation direction of the platen 120 and a rotation direction of the carrier head assembly 140 are shown to be the same as each other. This is just an example, and in one or more embodiments, a rotation direction of the platen 120 and a rotation direction of the carrier head assembly 140 may be different from each other.

The pad conditioner 160 may be disposed adjacent to the polishing pad 110. The pad conditioner 160 may perform a conditioning process or a break-in process on the polishing surface 110S of the polishing pad 110. Thus, the pad conditioner 160 may stably maintain the polishing surface 110S of the polishing pad 110 so that the wafer W may be effectively polished during the polishing process.

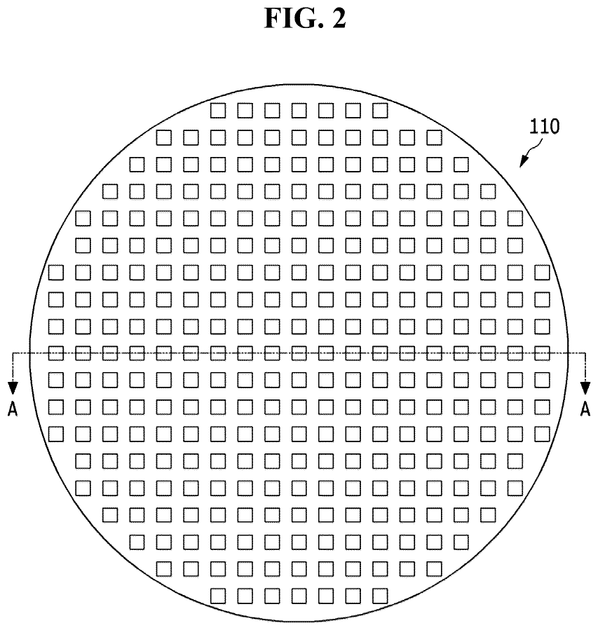

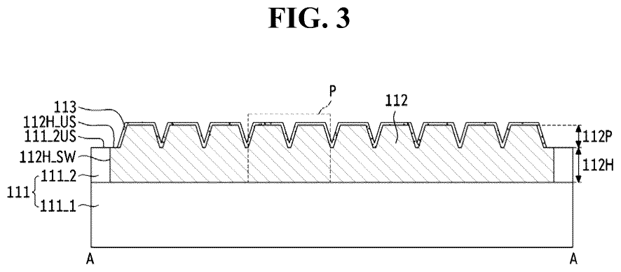

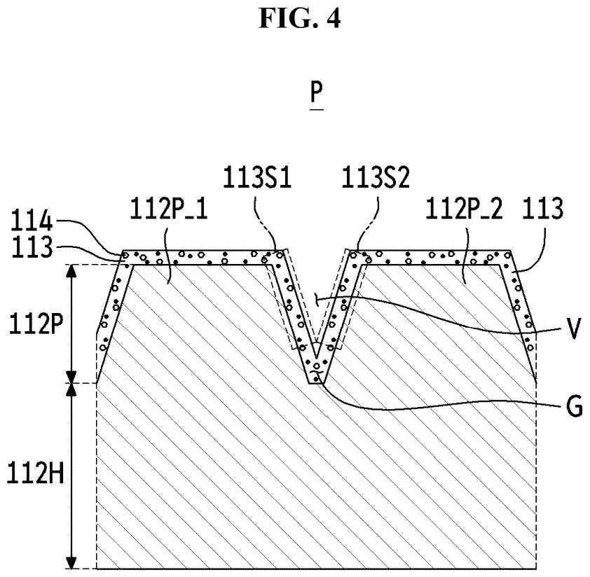

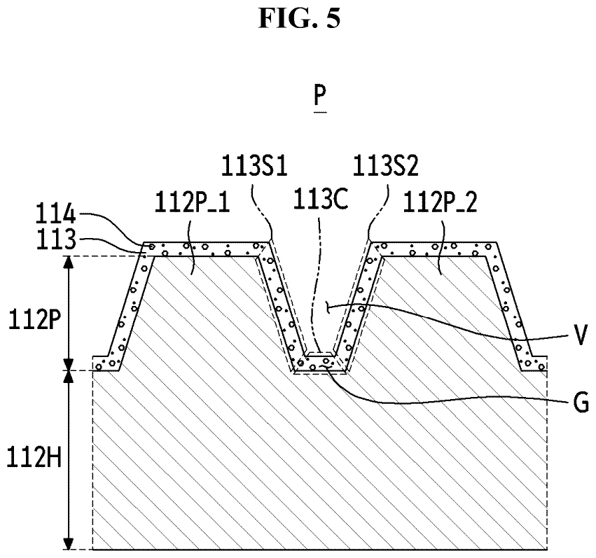

FIG. 2 is a diagram illustrating a CMP polishing pad according to one or more embodiments. FIG. 3 is a cross-sectional view taken along A-A in FIG. 2 according to one or more embodiments. FIG. 4 and FIG. 5 are enlarged views of examples of portion P of FIG. 3 according to one or more embodiments.

Referring to FIG. 2 and FIG. 3, the CMP polishing pad (hereinafter referred to as a polishing pad for convenience) may include a base layer 111, a polishing layer 112, and a coating layer 113.

The base layer 111 may include a first portion 111_1 and a second portion 111_2. The first portion 111_1 may extend in a horizontal direction. The second portion 111_2 may extend in a vertical direction from the first portion 111_1. The polishing layer 112, which will be described later, may be disposed on the first portion 111_1. The polishing layer 112 may be disposed to be between ends of the second portion 111_2. In one or more embodiments, the polishing layer 112 may be disposed on the second portion 111_2.

The base layer 111 may be a polymer layer. In one or more embodiments, the base layer 111 may include polyethylene terephthalate (PET), polyethylene naphthalate (PEN), polyetheretherketone (PEEK), polyimide (PI), or polybenzoxazole (PBO).

The polishing layer 112 may be disposed on the base layer 111. The polishing layer 112 may be disposed on the first portion 111_1 and the second portion 111_2 of the base layer 111. The polishing layer 112 may be disposed to be between ends of the second portion 111_2. The polishing layer 112 may be surrounded by the base layer 111. That is, the polishing layer 112 may be surrounded by the second portion 111_2 of the base layer 111. The polishing layer 112 may include a polyurethane material.

The polishing layer 112 may include a horizontal portion 112H and a plurality of protrusions 112P.

The horizontal portion 112H may contact the first portion 111_1 and the second portion 111_2 of the base layer 111. The horizontal portion 112H may contact an upper surface of the first portion 111_1 of the base layer 111. The horizontal portion 112H may contact the second portion 111_2 of the base layer 111. For example, a side surface 112H_SW of the horizontal portion 112H may contact the second portion 111_2 of the base layer 111. The second portion 111_2 of the base layer 111 may cover at least a portion of the side surface 112H_SW of the horizontal portion 112H.

An upper surface 112H_US of the horizontal portion 112H may be substantially coplanar with an upper surface 111_2US of the second portion 111_2 of the base layer 111. That is, the upper surface 112H_US of the horizontal portion 112H and the upper surface 111_2US of the second portion 111_2 of the base layer 111 may be at the same vertical level.

The plurality of protrusions 112P may protrude in the vertical direction from the horizontal portion 112H. The plurality of protrusions 112P may be arranged to be spaced apart from each other in the horizontal direction. The plurality of protrusions 112P may directly contact the wafer in the CMP process. In other words, the polishing of the wafer may be achieved by the plurality of protrusions 112P.

The plurality of protrusions 112P may not overlap the second portion 111_2 of the base layer 111 in the horizontal direction. The plurality of protrusions 112P may not contact the second portion 111_2 of the base layer 111.

The coating layer 113 may be disposed on the polishing layer 112. The coating layer 113 may extend conformally along the horizontal portion 112H and the protrusions 112P of the polishing layer 112. In one or more embodiments, the coating layer 113 may conformally cover the protrusions 112P and portions of the horizontal portion 112H that are between the protrusion 112P, while not covering ends of the horizontal portion 112H that contact the second portion 111_2 of the base layer 111.

The polishing layer 112 may have a concave-convex shape. That is, the polishing layer 112 may have a shape in which a plurality of protrusions 112P protrude from a horizontal portion 112H with a space between each of the plurality of protrusions 112P defined by exposed portions of the horizontal portion 112H. Thus, the coating layer 113 may extend conformally along each of the plurality of protrusions 112P and the exposed portions of the horizontal portion 112H that is between each of the plurality of protrusions 112P. In one or more embodiments, the coating layer 113 may extend conformally along all of the plurality of protrusions 112P and the entire horizontal portion 112H.

The coating layer 113 may include a polymer and diamond particles 114.

The polymer may be disposed on the polishing layer 112. The polymer may extend along a profile of the polishing layer 112. Specifically, the polymer may extend along a profile of the horizontal portion 112H and the protrusions 112P of the polishing layer 112. The polymers may be deposited thereon using chemical vapor deposition (CVD).

The diamond particles 114 may be deposited using CVD. The diamond particles 114 may be contained in the polymer. That is, the diamond particles 114 may be dispersed in the polymer. The polymer may serve as a bond so that the diamond particles 114 are disposed on the polishing layer 112.

Referring to FIG. 4 and FIG. 5, the plurality of protrusions 112P of the polishing layer 112 may include a first protrusion 112P_1 and a second protrusion 112P_2. The polishing layer 112 may include a groove G defined by the horizontal portion 112H, the first protrusion 112P_1 and the second protrusion 112P_2.

In FIG. 4, the coating layer 113 may extend along a profile of the groove G. The coating layer 113 may include a first inclined portion 113S1 which fills a portion of the groove G and are disposed on the first protrusion 112P_1, and a second inclined portion 113S2 which fills a portion of the groove G and is disposed on the second protrusion 112P_2. The coating layer 113 may include a valley area V defined by the first inclined portion 113S1 and the second inclined portion 113S2.

In FIG. 5, the coating layer 113 may include the first inclined portion 113S1 filling the portion of the groove G and disposed on the first protrusion 112P_1, the second inclined portion 113S2 filling the portion of the groove G and disposed on the second protrusion 112P_2, and a connection portion 113C which connects the first inclined portion 113S1 and the second inclined portion 113S2 to each other. The coating layer 113 may include a valley area V defined by the first inclined portion 113S1, the second inclined portion 113S2, and the connection portion 113C.

During the CMP process, the polishing pad may be filled with the SiO₂ film, thereby causing clogging or glazing. When the polishing pad is filled with the SiO₂ film such that the clogging or glazing occurs, the polishing rate may decrease and thus the efficiency of the polishing process may decrease.

However, the polishing pad 110 according to one or more embodiments may include the base layer 111, the polishing layer 112 disposed on the base layer 111, and the coating layer 113 disposed on the polishing layer 112 and containing the diamond particles 114. During the CMP process, the diamond particles 114 contained in the coating layer 113 play a polishing role, so that the polishing rate may be improved. In other words, the CMP process efficiency may be physically improved. Furthermore, the diamond particles 114 contained in the coating layer 113 may remove the SiO₂ film filling the valley area V to suppress the clogging or glazing phenomenon. In other words, in the polishing pad 110 according to one or more embodiments, the coating layer 113 containing the diamond particles 114 may prevent the clogging or glazing phenomenon during processing of the SiO₂ film, and at the same time, the diamond particles 114 play a polishing role, such that the polishing efficiency and the polishing rate may be improved.

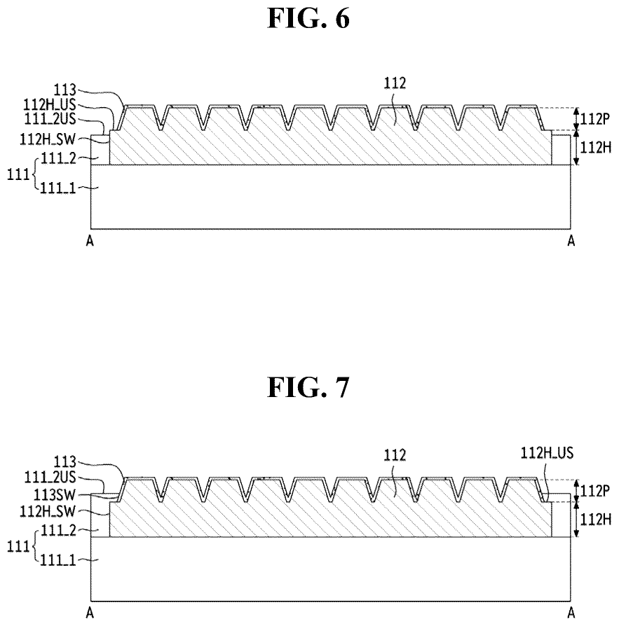

FIG. 6 and FIG. 7 are diagrams illustrating a CMP polishing pad according to one or more embodiments. Description of aspects the same as or similar to those described above may be omitted.

Referring to FIG. 6, the second portion 111_2 of the base layer 111 may contact the horizontal portion 112H of the polishing layer 112. Based on the upper surface of the first portion 111_1 of the base layer 111, the upper surface 111_2US of the second portion 111_2 of the base layer 111 may be positioned at a lower position than a position of the upper surface 112H_US of the horizontal portion 112H of the polishing layer 112. That is, the vertical level of the upper surface 111_2US of the second portion 111_2 of the base layer 111 may be lower than the vertical level of the upper surface 112H_US of the horizontal portion 112H of the polishing layer 112. Accordingly, a portion of the side surface 112H_SW portion of the horizontal portion 112H of the polishing layer 112 may not be covered with the second portion 111_2 of the base layer 111 so as to be exposed.

Referring to FIG. 7, the second portion 111_2 of the base layer 111 may contact the horizontal portion 112H of the polishing layer 112 and the coating layer 113. The second portion 111_2 of the base layer 111 may contact at least a portion of the side surface 113SW of the coating layer 113. However, a vertical level of the upper surface 111_2US of the second portion 111_2 of the base layer 111 may be lower than a vertical level of the upper surface of the protrusion 112P of the polishing layer 112. The second portion 111_2 of the base layer 111 may cover an entirety of the side surface 112H_SW of the horizontal portion 112H of the polishing layer 112. The second portion 111_2 of the base layer 111 may cover the upper surface 112H_US of the horizontal portion 112H at an end of the polishing layer 112. That is, the upper surface 111_2US of the second potion 111_2 of the base layer 111 may extend over the upper surface 112H_US of the horizontal portion 112H and contact the coating layer 113 on an outermost side protrusion of the protrusions 112P. Therefore, the horizontal portion 112H of the polishing layer 112 may not be exposed. Based on the upper surface of the first portion 111_1 of the base layer 111, the upper surface 111_2US of the second portion 111_2 of the base layer 111 may be positioned at a higher position than that of the upper surface 112H_US of the horizontal portion 112H of the polishing layer 112. That is, the vertical level of the upper surface 111_2US of the second portion 111_2 of the base layer 111 may be higher than the vertical level of the upper surface 112H_US of the horizontal portion 112H of the polishing layer 112.

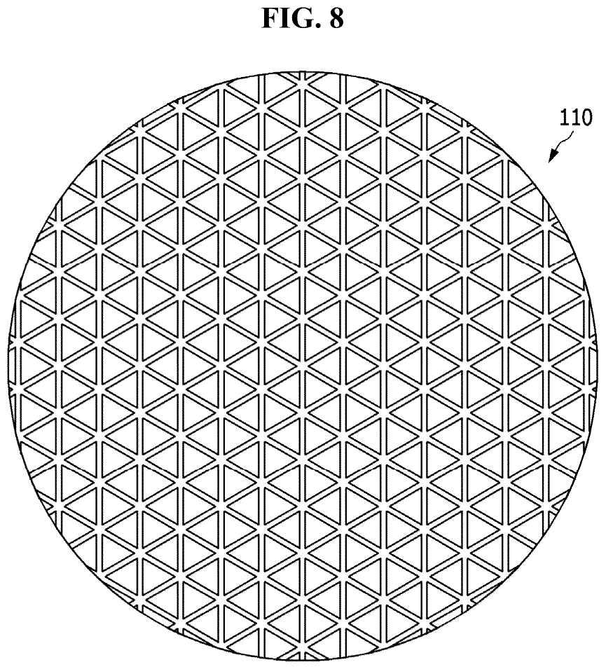

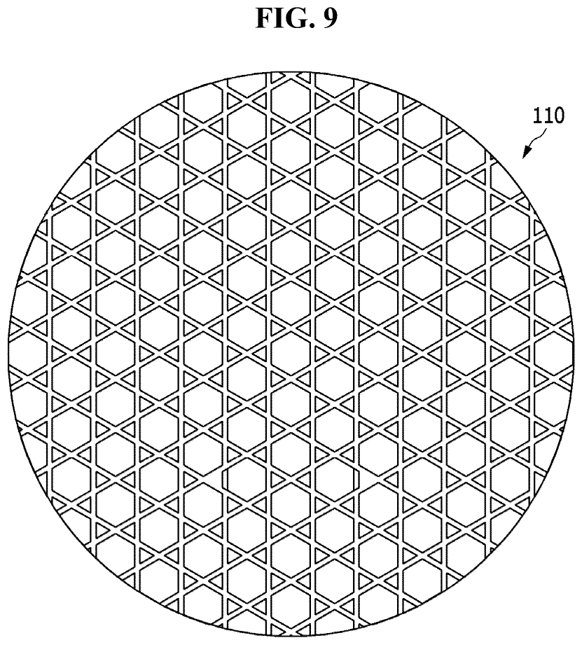

FIG. 8 and FIG. 9 are diagrams illustrating a CMP polishing pad according to one or more embodiments. Description of aspects the same as or similar to those described above may be omitted.

Referring to FIG. 8 and FIG. 9, a shape of the protrusion 112P of the polishing layer 112 of the polishing pad 110 is not limited to that shown in FIG. 2. In a plan view, the protrusion 112P of the polishing layer 112 may be a triangular pattern, as shown in FIG. 8. Alternatively, in a plan view, the protrusion 112P of the polishing layer 112 may be a hexagonal pattern.

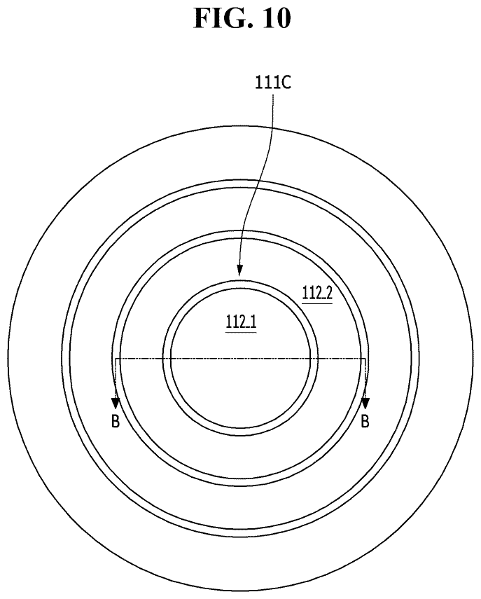

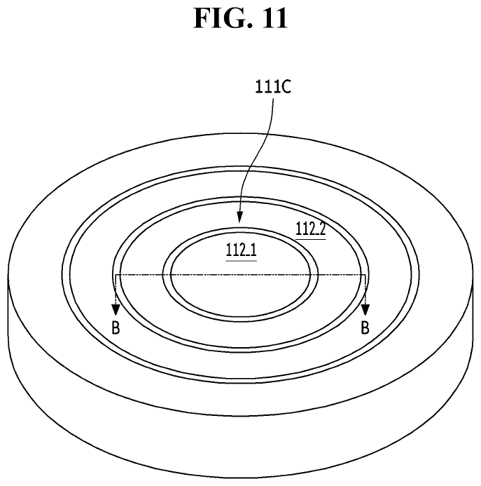

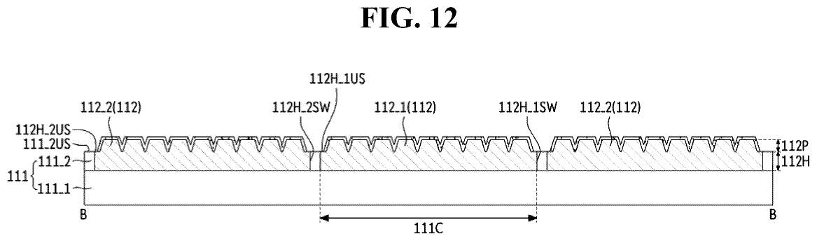

FIG. 10 to FIG. 11 are diagrams illustrating a CMP polishing pad according to one or more embodiments. FIG. 11 is a perspective view of FIG. 10. FIG. 12 is a cross-sectional view taken along B-B in FIG. 10 and FIG. 11 according to one or more embodiments. Description of aspects the same as or similar to those described above may be omitted.

Referring to FIG. 10 to FIG. 12, a plurality of polishing layers 112 of different shapes may be disposed on the base layer 111. For example, the base layer 111 may include a center area 111C. A circular polishing layer 112 may be disposed on the center area 111C of the base layer 111, and another polishing layer 112 surrounding the polishing layer 112 disposed on the center area 111C is disposed.

The polishing layer 112 may include a first polishing layer 112_1 disposed on the center area 111C and a second polishing layer 112_2 surrounding the first polishing layer 112_1 and spaced apart from the first polishing layer 112_1. Each of the first polishing layer 112_1 and the second polishing layer 112_2 may include the horizontal portion 112H and the protrusions 112P.

The coating layer 113 may be disposed on the first polishing layer 112_1 and the second polishing layer 112_2. The coating layer 113 may extend along a profile of the horizontal portion 112H and the protrusion 112P of each of the first polishing layer 112_1 and the second polishing layer 112_2. The coating layer 113 may include the polymer and the diamond particles 114. The coating layer 113 may be provided as a plurality of coating layers 113, with a specific coating layer for each of the first polishing layer 112_1 and the second polishing layer 112_2, where the plurality of coating layers are separated by the partition between the center area 111C and the peripheral areas of the base layer 111 (i.e., the partitions corresponding to the second portions 111_2 of the base layer 112 between each of the sets of plurality of protrusions as shown in FIG. 12). The coating layer 113 may be substantially the same as that set forth above with reference to FIG. 2 to FIG. 5.

The base layer 111 may include the first portion 111_1 extending in the horizontal direction and the second portion 111_2 extending in the vertical direction from the first portion 111_1.

The second portion 111_2 of the base layer 111 may be disposed between the first polishing layer 112_1 and the second polishing layer 112_2. The second portion 111_2 of the base layer 111 may contact at least a portion of the side surface 112H_2SW of the horizontal portion 112H of the second polishing layer 112_2. The second portion 111_2 of the base layer 111 may contact at least a portion of the side surface 112H_1SW of the horizontal portion 112H of the first polishing layer 112_1.

The upper surface 111_2US of the second portion 111_2 of the base layer 111 may be substantially coplanar with the upper surface 112H_1US of the horizontal portion 112H of the first polishing layer 112_1 and the upper surface 112H_2US of the horizontal portion 112H of the second polishing layer 112_2. In one or more embodiments, the vertical level of the upper surface 111_2US of the second portion 111_2 of the base layer 111 may be higher or lower than the vertical level of each of the upper surface 112H_1US of the horizontal portion 112H of the first polishing layer 112_1 and the second the upper surface 112H_2US of the horizontal portion 112H of the polishing layer 112_2.

As shown in FIG. 10 to FIG. 12, one polishing layer 112 having a circular shape may be disposed on the center area 111C of the base layer 111, and another polishing layer 112 may be disposed around the polishing layer 112 disposed on the center area 111C. In this case, the uniformity of the protrusions 112P of the polishing layer 112 may be increased when the break-in process is performed. The uniformity of the protrusions 112P increases, such that the CMP process efficiency may increase.

FIG. 13 to FIG. 16 are diagrams illustrating a CMP polishing pad according to one or more embodiments. Description of aspects the same as or similar to those described above may be omitted.

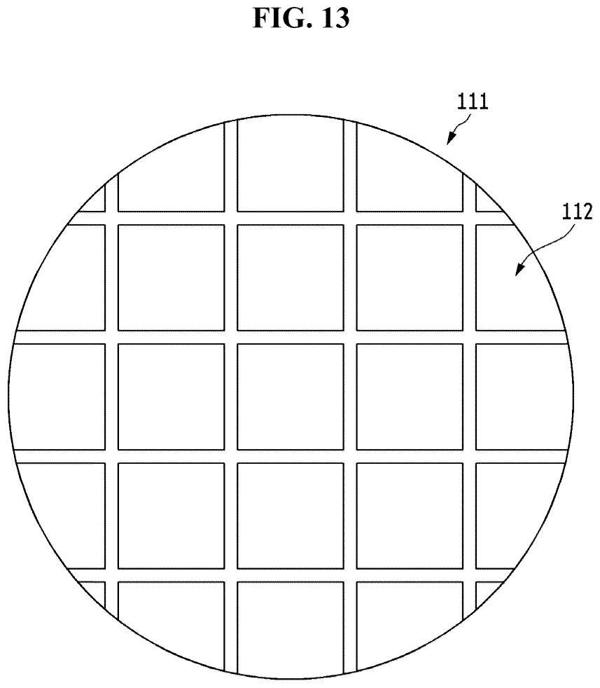

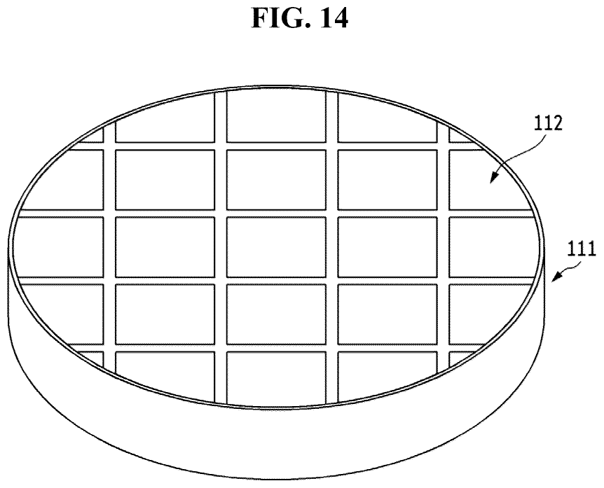

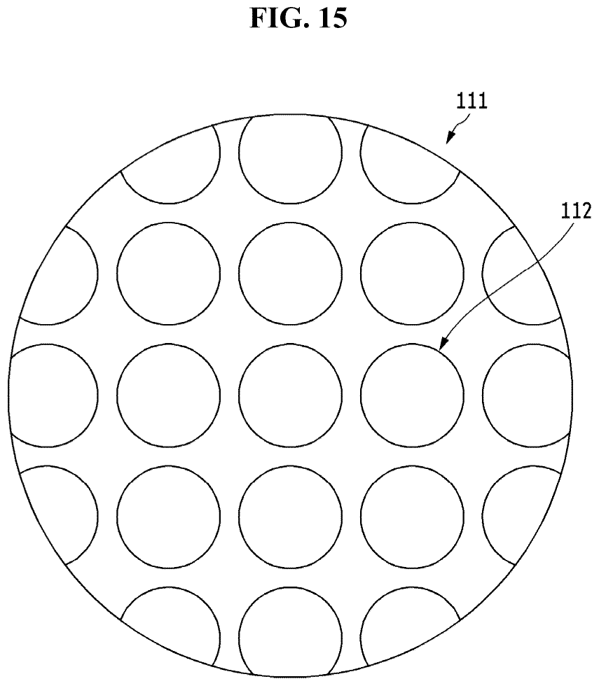

FIG. 13 to FIG. 16 are diagrams illustrating a shape of the polishing layer 112 disposed on the base layer 111. Referring to FIG. 13 and FIG. 14, the polishing layers 112 of the same square shape may be arranged on the base layer 111, and a portion outside each polishing layer on the base layer 111 may be cut away. Referring to FIG. 15 and FIG. 16, the polishing layers 112 of the same circular shape may be disposed on the base layer 111, while a portion outside each polishing layer on the base layer 111 may be cut away. The shape of each of the polishing layers 112 arranged on the base layer 111 is not limited to the circular, square, etc., and may have various other shapes.

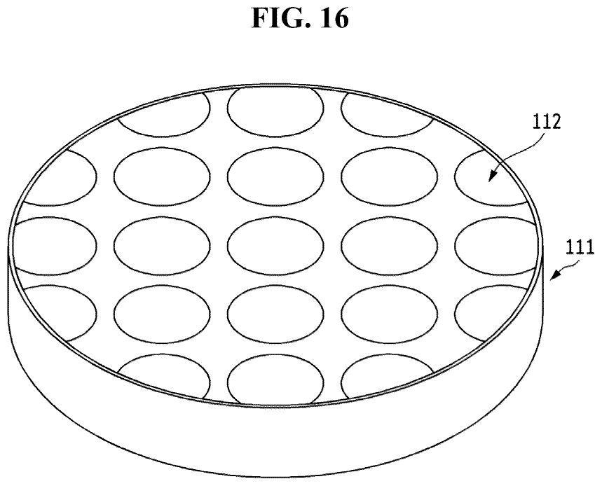

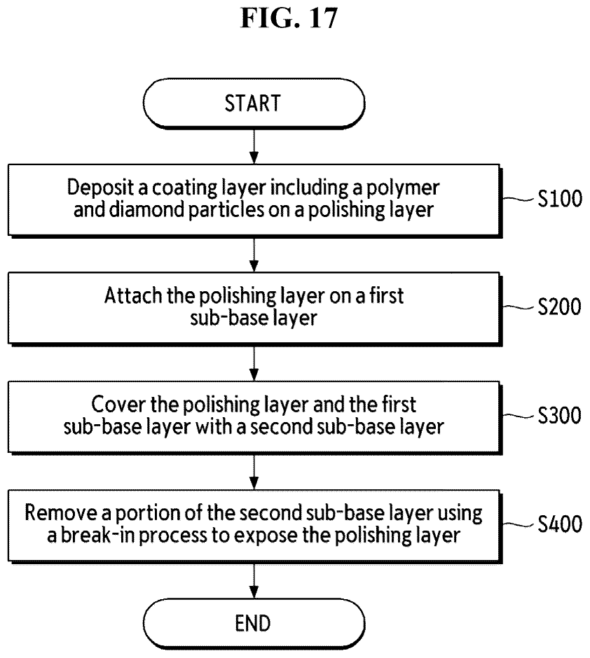

FIG. 17 to FIG. 22 are diagrams illustrating a method for manufacturing a CMP polishing pad according to one or more embodiments. Description of aspects the same as or similar to those described above may be omitted.

Referring to FIG. 17 to FIG. 19, first, the coating layer including the polymer and the diamond particles may be deposited on the polishing layer in operation S100.

The coating layer 113 may be formed on the polishing layer 112 using a CVD method 500. The coating layer 113 may include the polymer or the resin. The coating layer 113 may include the diamond particles dispersed in the polymer or resin.

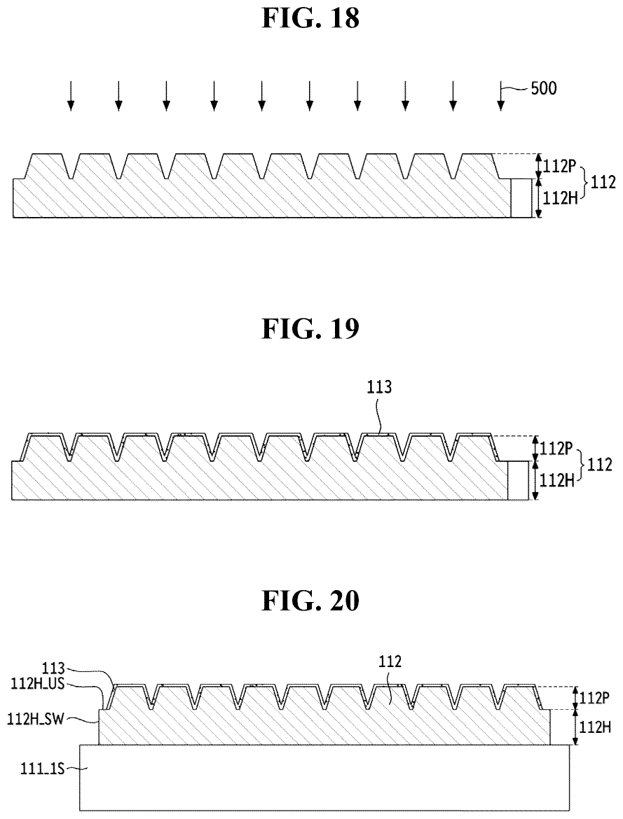

In the method for manufacturing the CMP polishing pad according to one or more embodiments, the polishing layer 112 and the coating layer 113 are manufactured separately from the base layer 111. That is, in FIG. 18 and FIG. 19, the coating layer 113 containing the diamond particles may be deposited on the polishing layer 112 separately from the base layer 111, such that some of the components of the polishing pad 110 may be formed.

Referring to FIG. 17 and FIG. 20, the polishing layer may then be attached on a first sub-base layer in in operation S200.

A resulting structure in FIG. 19 may be attached to the first sub-base layer 111_1S. Accordingly, the polishing layer 112 and the coating layer 113 may be formed on the first sub-base layer 111_1S.

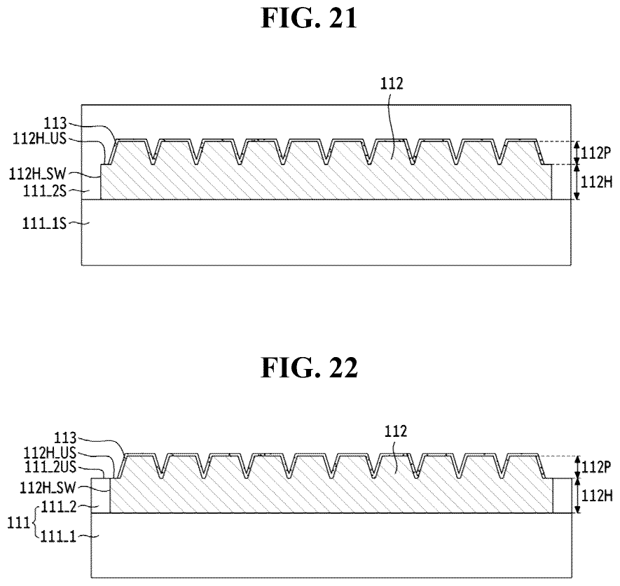

Referring to FIG. 17 and FIG. 21, the polishing layer and the first sub-base layer may be covered with a second sub-base layer in operation S300.

The second sub-base layer 111_2S may be formed on the first sub-base layer 111_1S. The second sub-base layer 111_2S may cover the polishing layer 112 and the coating layer 113. The second sub-base layer 111_2S may cover the side surface 112H_SW of the polishing layer 112. The second sub-base layer 111_2S may cover the upper surface 112H_US of the horizontal portion 112H of the polishing layer 112. The second sub-base layer 111_2S may cover the protrusions 112P of the polishing layer 112.

Referring to FIG. 17 and FIG. 22, a portion of the second sub-base layer may be removed using a break-in process to expose the polishing layer in operation S400.

The break-in process may be performed such that a portion of the second sub- base layer 111_2S may be removed. The portion of the second sub-base layer 111_2S may be removed to expose the protrusion 112P of the polishing layer 112 and the coating layer 113.

The break-in process may be performed such that the first portion 111_1 and the second portion 111_2 of the base layer 111 may be formed. The break-in process may continue until the upper surface 111_2US of the second portion 111_2 of the base layer 111 is at the same vertical level as the vertical level of the upper surface 112H_US of the horizontal portion 112H of the polishing layer 112. In one or more embodiments, the break-in process may be performed so that the vertical level of the upper surface 111_2US of the second portion 111_2 of the base layer 111 may be lower than the vertical level of the upper surface 112H_US of the horizontal portion 112H of the polishing layer 112, as shown in FIG. 6. Alternatively, the break-in process may be performed until the second portion 111_2 of the base layer 111 contacts at least a portion of the coating layer 113 as shown in FIG. 7.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A chemical mechanical polishing (CMP) polishing pad, comprising:
a base layer;
a polishing layer on the base layer and having a concave-convex pattern shape; and
a coating layer on the polishing layer and comprising diamond particles.

2. The CMP polishing pad of claim 1, wherein the coating layer further comprises a polymer, and
wherein the diamond particles are dispersed in the polymer.

3. The CMP polishing pad of claim 1, wherein the polishing layer comprises a horizontal portion and a plurality of protrusions, and
wherein the coating layer extends conformally along the plurality of protrusions and portions of the horizontal portion between the plurality of protrusions.

4. The CMP polishing pad of claim 3, wherein the plurality of protrusions comprise a first protrusion and a second protrusion,
wherein the polishing layer comprises a groove defined by the horizontal portion, the first protrusion and the second protrusion,
wherein the coating layer further comprises:
a first inclined portion on the first protrusion and filling a first portion of the groove; and
a second inclined portion on the second protrusion and filling a second portion of the groove.

5. The CMP polishing pad of claim 4, wherein the coating layer further comprises a valley area between the first inclined portion and the second inclined portion.

6. The CMP polishing pad of claim 4, wherein the coating layer further comprises a connection portion on the horizontal portion and connecting the first inclined portion to the second inclined portion.

7. The CMP polishing pad of claim 1, wherein the base layer comprises a first portion extending in a horizontal direction and a second portion extending in a vertical direction and from the first portion,
wherein the polishing layer comprises a horizontal portion and a plurality of protrusions, and
wherein the second portion surrounds at least a first portion of a side surface of the horizontal portion.

8. The CMP polishing pad of claim 7, wherein an upper surface of the second portion is substantially coplanar with an upper surface of the horizontal portion.

9. The CMP polishing pad of claim 7, wherein an upper surface of the second portion is at a vertical level that is lower than a vertical level of an upper surface of the horizontal portion, and
wherein a second portion of a side surface of the horizontal portion is exposed.

10. The CMP polishing pad of claim 7, wherein the second portion contacts at least a portion of a side surface of the coating layer.

11. A chemical mechanical polishing (CMP) polishing pad comprising:
a base layer comprising a center area;
a polishing layer comprising:
a first polishing layer on the center area; and
a second polishing layer on the base layer and at least partially surrounding the first polishing layer, wherein the second polishing layer is spaced apart from the first polishing layer; and
a coating layer on the polishing layer and comprising a polymer and diamond particles,
wherein the first polishing layer and the second polishing layer have a concave-convex pattern shape,
wherein the first polishing layer comprises a first horizontal portion and a first plurality of protrusions, and
wherein the second polishing layer comprises a second horizontal portion and a second plurality of protrusions.

12. The CMP polishing pad of claim 11, wherein the coating layer extends conformally along the first plurality of protrusions and portions of the first horizontal portion between the first plurality of protrusions, and conformally along the second plurality of protrusions and portions of the second horizontal portion between the second plurality of protrusions.

13. The CMP polishing pad of claim 11, wherein the first plurality of protrusions comprise a first protrusion and a second protrusion,
wherein the first polishing layer further comprises a groove defined by the first horizontal portion, the first protrusion and the second protrusion,
wherein the coating layer further comprises:
a first inclined portion on the first protrusion and filling a first portion of the groove;
a second inclined portion on the second protrusion and filling a second portion of the groove; and
a valley area between the first inclined portion and the second inclined portion.

14. The CMP polishing pad of claim 11, wherein the base layer further comprises a first portion extending in a horizontal direction and a second portion extending in a vertical direction and from the first portion, and
wherein the second portion is between the first polishing layer and the second polishing layer.

15. The CMP polishing pad of claim 14, wherein the second portion contacts at least a portion of a side surface of the first horizontal portion of the first polishing layer and at least a portion of a side surface of the second horizontal portion of the second polishing layer.

16. The CMP polishing pad of claim 14, wherein an upper surface of the second portion is substantially coplanar with an upper surface of the first horizontal portion of the first polishing layer and substantially coplanar an upper surface of the second horizontal portion of the second polishing layer.

17. A chemical mechanical polishing (CMP) polishing pad comprising:
a base layer comprising a first portion extending in a horizontal direction and a second portion extending in a vertical direction and from the first portion;
a polishing layer on the base layer and having a concave-convex pattern shape, wherein the polishing layer comprises a horizontal portion and a plurality of protrusions; and
a coating layer on the polishing layer and comprising a polymer and diamond particles,
wherein the second portion contacts at least a portion of a side surface of the horizontal portion.

18. The CMP polishing pad of claim 17, wherein an upper surface of the second portion is substantially coplanar with an upper surface of the horizontal portion.

19. The CMP polishing pad of claim 17, wherein the plurality of protrusions comprise a first protrusion and a second protrusion,
wherein the polishing layer comprises a groove defined by the horizontal portion, the first protrusion and the second protrusion,
wherein the coating layer further comprises:
a first inclined portion on the first protrusion and filling a first portion of the groove;
a second inclined portion on the second protrusion and filling a second portion of the groove; and
a valley area between the first inclined portion and the second inclined portion.

20. The CMP polishing pad of claim 17, wherein the second portion is contacts at least a portion of a side surface of the coating layer.
